(19) United States
(12) Patent Application Publication
(10) Pub. No.: US 2026/0206384 A1
(43) Pub. Date: Jul. 16, 2026

(54) DISPLAY PANEL AND DISPLAY APPARATUS

(71) Applicants: Hefei Visionox Technology Co., Ltd., Hefei (CN); Visionox Technology Inc., Kunshan (CN)

(72) Inventors: Zhiwei ZHOU, Hefei (CN); Yingyu FENG, Kunshan (CN); Jinfang ZHANG, Hefei (CN); Qingfeng XU, Hefei (CN)

(73) Assignees: Hefei Visionox Technology Co., Ltd., Hefei (CN); Visionox Technology Inc., Kunshan (CN)

(21) Appl. No.: 19/386,117

(22) Filed: Nov. 11, 2025

(30) Foreign Application Priority Data
Nov. 14, 2024 (CN) 202411630827.0

(51) Int. Cl. H10H 29/37

(52) U.S. Cl. CPC H10H 29/37

(57) ABSTRACT

The present disclosure provides a display panel and a display apparatus. The display panel has an active area and a non-active area connected to the active area. The display panel includes a substrate, an isolation structure, and a plurality of light-emitting devices. The isolation structure is arranged on a side of the substrate and has at least one recessed portion, a plurality of isolation openings are located in the active area, and at least part of each light-emitting device is located in an isolation opening. The at least one recessed portion is located in the non-active area, and the at least one recessed portion is recessed from a side of the isolation structure facing away from the substrate toward the substrate.

### CROSS-REFERENCE TO RELATED APPLICATIONS

The present application claims priority to the Chinese Patent Application No. 202411630827.0, filed on Nov. 14, 2024, and the entire contents of the aforementioned application are hereby incorporated by reference in its entirety.

### FIELD

The present disclosure relates to the field of display, and in particular, to a display panel and a display apparatus.

### BACKGROUND

An organic light-emitting diode (OLED) is an organic thin-film electroluminescent device. which has attracted considerable attention and has been widely applied in electronic display products thanks to its advantages such as low power consumption, high luminance, wide angle of view, high contrast, and enabling flexible display.

However, abnormalities still occur between film layers in existing display panels.

During the preparation of conventional OLED display panels, light-emitting pixel patterning is typically implemented using a fine metal mask (FMM). FMM technology is mature and has rich experience in mass production. However, FMM technology also has problems such as limited precision and high costs. Fine metal mask-free technology eliminates the limitations of conventional OLED processes on display size, resolution, and other screen performances, and has the advantages of high performance, full-size coverage, and agile delivery. Patents CN118251982A, CN115666161A, CN116648095A, CN117062489A, CN118678742A, CN118785761A, CN115224220A, CN118678729A, CN118660529A and CN118660589A describe contents related to the fine metal mask-free technology for reference.

### SUMMARY

An object of the present disclosure is to provide a display panel and a display apparatus, to solve the abnormal phenomena of film layers in existing display panels.

To achieve the above object, the present disclosure provides a display panel, the display panel having an active area and a non-active area connected to the active area. The display panel includes a substrate, an isolation structure, and a plurality of light-emitting devices. The isolation structure is arranged on a side of the substrate and has at least one recessed portion, the plurality of isolation openings being located in the active area, the at least one recessed portion being located in the non-active area, and the at least one recessed portion being recessed from a side of the isolation structure facing away from the substrate toward the substrate. At least part of each light-emitting device is located in an isolation opening.

The present disclosure further provides a display apparatus, including the display panel as described above.

The advantages of the present disclosure are as follows. In the display panel and the display apparatus of the present disclosure, a recessed portion is provided in the non-active area of the display panel to alleviate stress in the isolation structure, thereby solving the problem of abnormalities that easily occur between adjacent film layers in the non-active area and improving the reliability of the display panel.

### BRIEF DESCRIPTION OF THE DRAWINGS

FIG. 1 is a schematic diagram of the area division of a display panel in an embodiment of the present disclosure;

FIG. 2 is a schematic diagram of a layered structure of a display panel in an active area in an embodiment of the present disclosure;

FIG. 3 is a schematic diagram of a layered structure of a display panel in a non-active area in an embodiment of the present disclosure;

FIG. 4 is a schematic diagram of a layered structure of a display panel in a non-active area in an embodiment of the present disclosure;

FIG. 5 is a schematic diagram of a layered structure of a display panel in a non-active area in other embodiments of the present disclosure;

FIG. 6 is a schematic diagram of a layered structure of a display panel in a non-active area in another embodiment of the present disclosure;

FIG. 7 is a schematic diagram of a layered structure of a display panel in a non-active area in another embodiment of the present disclosure; and

FIG. 8 is a schematic diagram of a layered structure of a display panel in a non-active area in other embodiments of the present disclosure.

The components in the drawings are shown as follows:
1. Display panel; AA. Active area;
NA. Non-active area; 10. Substrate;
11. Driving layer; 12. Conductive layer;
13. Planarization layer; 14. Power data line;
20. Pixel defining layer; 21. Pixel opening;
23. First via;
30. Isolation structure; 30A. Isolation portion;
30B. Overlapping portion; 31. Support layer;
32. Blocking layer; 33. Isolation opening;
34. First surface; 35. Second surface;
40. Light-emitting device; 41. First electrode;
42. Light-emitting layer; 43. Second electrode;
50. Recessed portion; 50A. First recessed portion;
50B. Second recessed portion; 51. First opening;
52. Second opening; 60. First via;
70. Second via; 80. Third via.

### DETAILED DESCRIPTION OF THE EMBODIMENTS

In related display technologies, to achieve high-resolution and colorized organic light-emitting diodes (OLEDs) and to better solve problems such as low resolution of OLED electrode film layers and low device yield, an electrode isolation structure has been introduced. That is, in device preparation, instead of using a metal mask, an isolation structure is prepared on a driving layer before evaporation of an organic thin film and metal electrode layers. The isolation structure isolates different pixels of the device, thereby enabling the formation of a pixel array. However, the inventors have found in practical production that the problem of peeling of film layers frequently occurs in a non-active area of a display panel.

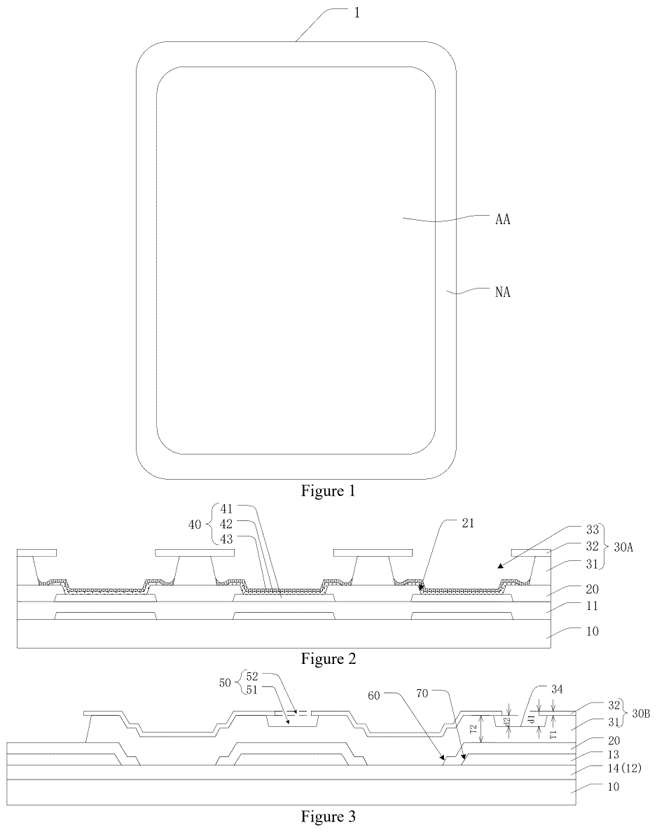

Based on the problems proposed in the above related display technologies, embodiments of the present disclosure provide a display panel 1. As shown in FIG. 1, the display panel 1 has an active area AA and a non-active area NA connected to the active area AA. The active area AA is configured to present a display image and is provided with a plurality of light-emitting devices 40, each of which can be activated under control. The outermost light-emitting device 40 is considered as the boundary between the active area AA and the non-active area NA. When the plurality of light-emitting devices 40 include both non-virtual light-emitting devices and virtual light-emitting devices, the outermost non-virtual light-emitting device is considered as the boundary between the active area AA and the non-active area NA. The non-active area NA is arranged around the active area AA and is provided with a plurality of signal traces. Devices in the active area AA are electrically connected to a bonding assembly via the signal traces, to acquire control signals output by the bonding assembly and activate the corresponding light-emitting devices 40 according to the control signals. The bonding assembly may include at least one of electronic devices, such as a flexible printed circuit (FPC) and a driving chip.

As shown in FIGS. 2 and 3, the display panel 1 includes a substrate 10, an isolation structure 30, and a plurality of light-emitting devices 40. The isolation structure 30 is arranged on a side of the substrate 10 and includes an isolation portion 30A located in the active area AA and an overlapping portion 30B located in the non-active area NA, with the isolation portion 30A and the overlapping portion 30B being integrally formed. The isolation portion 30A encloses a plurality of isolation openings 33 in the active area AA, and is used to block evaporation materials and disconnect the evaporation materials between adjacent isolation openings 33, thereby isolating a plurality of light-emitting devices 40. The overlapping portion 30B in the non-active area NA is provided with a plurality of recessed portions 50 to solve the problem of peeling between the isolation structure 30 and adjacent film layers. At least part of each light-emitting device 40 is arranged within a corresponding isolation opening 33. Each light-emitting device 40, as an independent light-emitting unit, can be activated or deactivated according to a corresponding display signal under the drive of the substrate 10.

Further, the display panel 1 includes a driving layer 11 arranged on a side of the substrate 10 and located in the active area AA and the non-active area NA. In the active area AA, the driving layer 11 is provided with a plurality of thin-film transistors arranged in an array. The thin-film transistors are configured to control the conduction of corresponding circuits, and each light-emitting device 40 is electrically connected to at least one thin-film transistor. The driving layer 11 further includes a conductive layer 12. The conductive layer 12 includes at least one power signal line located in the non-active area NA and configured to supply power signals to the light-emitting devices 40 in the active area AA. The conductive layer 12 further includes other signal traces for signal transmission, such as data signal lines and compensation signal lines. In the conductive layer 12, one end of each of at least part of the signal traces is located in the active area AA and is electrically connected to the thin-film transistor located in the active area AA. The other end of each of the signal traces extends from the active area AA to the non-active area NA and is electrically connected to the bonding assembly. The signal traces in the conductive layer 12 are configured to transmit signals output from the bonding assembly to the corresponding thin-film transistors. The thin-film transistors conduct the corresponding circuits according to the received signals, thereby activating the corresponding light-emitting devices 40 to display an image. Moreover, the bonding assembly can also realize the switching of display images by sending different display signals.

In the driving layer 11, at least one insulating layer may be provided between two adjacent conductive film layers for isolation and insulation, preventing short circuits in the circuits on the substrate 10. Further, in addition to preventing short circuits in the circuits, different insulating layers can also have other functions, for example, a planarization layer 13 for planarizing a surface of the substrate 10, the planarization layer 13 being positioned between the power signal line and the isolation structure 30. A material of the insulating layer may include at least one of an inorganic material or an organic material, and the materials of different insulating layers may differ. A material of the planarization layer 13 includes an organic material.

The display panel 1 further includes a pixel defining layer 20 arranged on a side of the driving layer 11 facing away from the substrate 10. The pixel defining layer 20 is located in the active area AA and the non-active area NA. The pixel defining layer 20 encloses a plurality of pixel openings 21 in the active area AA, and at least part of each light-emitting device 40 is arranged in a corresponding pixel opening 21. The isolation structure 30 is arranged on a side of the pixel defining layer 20 facing away from the substrate 10, and the isolation openings 33 in the active area AA are in communication with the corresponding pixel openings 21, allowing materials of the light-emitting devices 40 to be evaporated into the pixel openings 21.

Each light-emitting device 40 includes a first electrode 41, a light-emitting layer 42, and a second electrode 43. The first electrode 41 is arranged on a side of the driving layer 11 and is located between the pixel defining layer 20 and the driving layer 11, and the surface of the first electrode 41 is partially exposed in the corresponding pixel opening 21. The light-emitting layer 42 is arranged in the corresponding pixel opening 21 to cover the exposed surface of the first electrode 41 in the corresponding pixel opening 21 and extend from a surface of the first electrode 41 to the side of the pixel defining layer 20 facing away from the substrate 10. The second electrode 43 is stacked on a side of the light-emitting layer 42 facing away from the substrate 10, and extends from a surface of the light-emitting layer 42 facing away from the substrate 10 to a surface of the isolation structure 30 facing the isolation opening 33, thereby allowing the second electrode 43 to overlap with the isolation structure 30. The first electrode 41 of the light-emitting device 40 is electrically connected to the thin-film transistor in the substrate 10, and the second electrode 43 thereof is electrically connected to a power signal trace via the isolation structure 30. Upon conduction, the first electrode 41 and the second electrode 43 transport electrons and holes into the light-emitting layer 42, respectively. The electrons and holes combine in the light-emitting layer 42 to form excitons, converting electrical energy into light energy and allowing the light-emitting layer 42 to emit light, and thus activating the corresponding light-emitting device 40.

In particular, the isolation structure 30 includes a support layer 31 and a blocking layer 32, the support layer 31 and the blocking layer 32 surrounding the isolation openings 33. The support layer 31 is arranged on the side of the pixel defining layer 20 facing away from the substrate 10, and the blocking layer 32 is stacked on a side of the support layer 31 facing away from the substrate 10. A material of the support layer 31 includes a conductive material, and a material of the blocking layer 32 includes a metal material. In one embodiment, the material of the support layer 31 may be aluminum, and the material of the blocking layer 32 may be titanium.

Further, in the isolation opening 33, the second electrode 43 has a larger coverage area than the light-emitting layer 42. That is, an orthographic projection of the light-emitting layer 42 on the substrate 10 is located within an orthographic projection of the second electrode 43 on the substrate 10. The second electrode 43 extends from the light-emitting layer 42 to a sidewall of the support layer 31, thereby allowing the second electrode 43 to be electrically connected to the support layer 31. The second electrode 43 can acquire the power signals via the support layer 31. The cross-sectional profile of the support layer 31 located between two adjacent pixel openings 21 is trapezoidal, and a width of the support layer 31 on a side close to the blocking layer 32 is smaller than a width on a side close to the substrate 10. This facilitates the climbing of the second electrode 43 and reduces the difficulty of overlapping between the second electrode 43 and the support layer 31.

An end of the blocking layer 32 facing the isolation opening 33 protrudes beyond the support layer 31, that is, an orthographic projection of the blocking layer 32 on the substrate 10 covers an orthographic projection of the support layer 31 on the substrate 10, and the orthographic projection area of the blocking layer 32 on the substrate 10 is larger than the orthographic projection area of the support layer 31 on the substrate 10. Thus, the blocking layer 32 can completely shield the support layer 31, thereby preventing the material of the light-emitting layer 42 from being evaporated on the support layer 31 during the preparation of the light-emitting layer 42. During the preparation of the second electrode 43, the coverage area of the second electrode 43 can be made larger than the coverage area of the light-emitting layer 42 by adjusting the evaporation angle of a material of the second electrode 43. This facilitates the formation of the light-emitting layer 42 and the second electrode 43 with different coverage areas, thereby improving the overlap yield between the second electrode 43 and the support layer 31.

As shown in FIG. 3, in the non-active area NA, a plurality of recessed portions 50 are provided in the isolation structure 30, a plurality of first vias 60 are formed in the pixel defining layer 20, and a plurality of second vias 70 are formed in the planarization layer 13. The first vias 60 extend through the pixel defining layer 20, the second vias 70 extend through the planarization layer 13, and the first vias 60 and the second vias 70 are arranged in a one-to-one correspondence. That is, an orthographic projection of each first via 60 on the substrate 10 is located within an orthographic projection of a corresponding second via 70 on the substrate 10. The support layer 31 of the isolation structure 30 is electrically connected to the power signal line in the conductive layer 12 via the first via 60 and the second via 70, and a VSS power signal is transmitted via the power signal trace. Further, the pixel defining layer 20 covers a surface of the planarization layer 13 facing away from the conductive layer 12 and a side surface of the planarization layer 13 facing the second via 70. At least one recessed portion 50 is provided between two adjacent first vias 60 and second vias 70. The recessed portion 50 extends through the isolation structure 30, and an orthographic projection of the recessed portion 50 on the substrate 10 is located outside orthographic projections of the first via 60 and the second via 70 on the substrate 10. That is, the orthographic projection of the recessed portion 50 on the substrate 10 is located within an orthographic projection of the pixel defining layer 20 on the substrate 10 and an orthographic projection of the planarization layer 13 on the substrate 10. A spacing between two adjacent recessed portions 50 is less than or equal to 200 nm, and widths of the first via 60 and the second via 70 are less than 200 nm. For example, the spacing between two adjacent recessed portions 50 may be 150 nm, 100 nm, or 50 nm, and the widths of the first via 60 and the second via 70 may be 150 nm, 100 nm, or 50 nm.

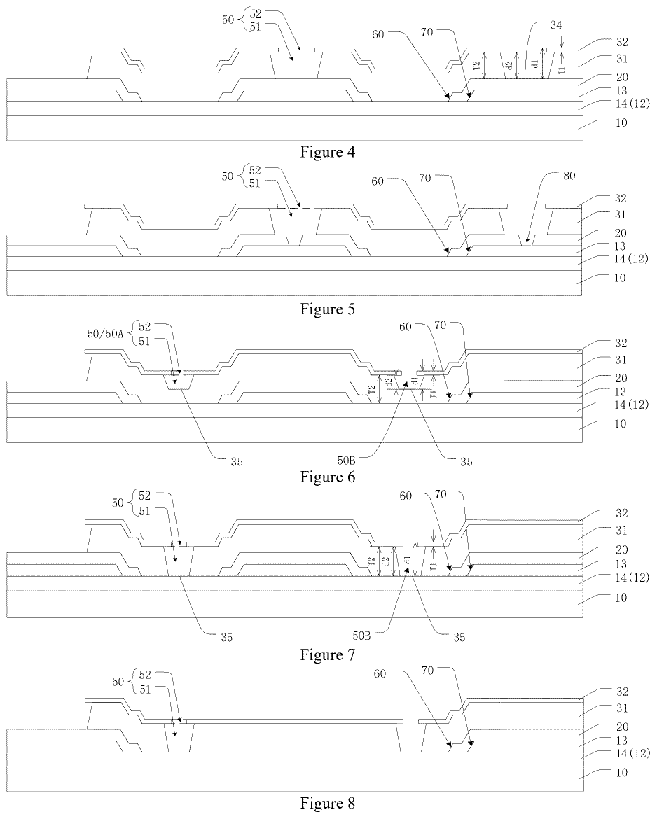

As shown in FIG. 3 or 4, the recessed portion 50 is recessed from a side of the isolation structure 30 facing away from the substrate 10 toward the substrate 10, and a depth of the recessed portion is a first depth d1. In a cross-section perpendicular to the substrate 10, the blocking layer 32 has a first film thickness T1, and the first depth d1 is greater than the first film thickness T1. That is, the recessed portion 50 extends through the blocking layer 32. The recessed portion 50 is recessed from the side of the support layer 31 facing away from the substrate 10 toward the substrate 10, with a depth of a second depth d2. The support layer 31 has a second film thickness T2, and the second depth d2 is less than or equal to the second film thickness T2. That is, the recessed portion 50 may or may not extend through the isolation structure 30.

In particular, each recessed portion 50 includes a first opening 51 and a second opening 52 that is in communication with the first opening 51. The first opening 51 is located on the side of the support layer 31 facing away from the substrate 10. As shown in FIGS. 3 and 4, the depth of the first opening 51 (i.e., the second depth d2) is less than or equal to the thickness of the support layer 31 (i.e., the second film thickness T2). That is, the first opening 51 may be embedded in a surface of the support layer 31 facing away from the substrate 10, as shown in FIG. 3, or may completely extend through the support layer 31, as shown in FIG. 4. The isolation structure 30 has a first surface 34 facing the pixel defining layer 20. When the first opening 51 extends through the support layer 31, a bottom wall of the first opening 51 is coplanar with the first surface 34, allowing a surface of the pixel defining layer 20 on the side facing away from the substrate 10 to be partially exposed in the recessed portion 50. When the first opening 51 does not extend through the support layer 31, the bottom wall of the recessed portion 50 is non-coplanar with the first surface 34 and is located on a side of the first surface 34 facing away from the substrate 10. The second opening 52 extends through the blocking layer 32, and an orthographic projection of the second opening 52 on the substrate 10 is located within an orthographic projection of the first opening 51 on the substrate 10, thereby enabling the second opening 52 to be in communication with the first opening 51. In one embodiment, the depth of the first opening 51 is smaller than the thickness of the support layer 31, and the recessed portion 50 does not extend through the support layer 31. In this way, part of the support layer 31 is retained at a bottom of the recessed portion 50. Retaining more support layer material can reduce the overall resistance of the support layer 31, thereby lowering the power consumption of the display panel 1.

To meet the bonding requirements between the support layer 31 and the power signal line, a large-area support layer 31 is prepared in the non-active area NA. However, the problem of peeling may easily occur between the large-area support layer 31 and the film layers (e.g., the blocking layer 32) prepared in subsequent processes, causing abnormalities in the film layers within the non-active area NA. Therefore, in the embodiments of the present disclosure, recessed portions 50 are provided in the non-active area NA to relieve stress in the support layer 31 and the blocking layer 32, thereby solving the problem of peeling that easily occurs between the large-area support layer 31 and the film layers prepared in subsequent processes in the non-active area NA, and improving the effect of bonding between the support layer 31 and other film layers in the non-active area NA.

It should be understood that, in other embodiments of the present disclosure, only one recessed portion 50 may be provided in the isolation structure 30. Providing a single recessed portion 50 can also solve the problem of peeling that easily occurs between the large-area support layer 31 and the film layers prepared in subsequent processes in the non-active area NA. Therefore, the number of recessed portions 50 is not specifically limited in the embodiments, that is, one or two or move recessed portions 50 may be provided.

Further, the recessed portion 50 may be prepared simultaneously with the isolation openings 33 in the active area AA. Therefore, a maximum width of the second opening 52 is smaller than a minimum width of the first opening 51 of the recessed portion 50. That is, the orthographic projection of the second opening 52 on the substrate 10 is located within the orthographic projection of the first opening 51 on the substrate 10, and the orthographic projection area of the second opening 52 on the substrate 10 is smaller than the orthographic projection area of the first opening 51 on the substrate 10. Moreover, the cross-sectional shape of the first opening 51 in a thickness direction of the display panel 1 is trapezoidal, and a width of the first opening 51 at an end close to the substrate 10 is smaller than a width at an end away from the substrate 10.

Further, in the display panel 1 provided in other embodiments of the present disclosure, as shown in FIG. 5, the display panel 1 further includes a plurality of third vias 80. Each third via 80 extends through the pixel defining layer 20, allowing a surface of the planarization layer 13 on a side facing away from the substrate 10 to be partially exposed through the third vias 80. The plurality of third vias 80 and the plurality of recessed portions 50 are arranged in a one-to-one correspondence, and each third via 80 is in communication with a corresponding recessed portion 50. In the cross-section perpendicular to the substrate 10, the third via 80 has a smaller width than the recessed portion 50. The layered structure of the display panel 1 is similar to that of the display panel 1 provided in the embodiments of the present disclosure, and thus will not be described in detail herein.

The embodiments of the present disclosure further provide a display apparatus, which may be an OLED display apparatus, including the display panel 1 as described above. The display apparatus may be any display device with a display function, such as a mobile phone, a notebook computer, or a tablet computer.

In the display panel and display apparatus provided in the embodiments of the present disclosure, a recessed portion is provided in the isolation structure located in the non-active area NA to alleviate stress in the isolation structure, thereby solving the problem of peeling that easily occurs between adjacent film layers of the isolation structure and improving the reliability of the display panel.

In another embodiment, based on the problems proposed in the above related display technologies, another embodiment of the present disclosure further provides a display panel 1. As shown in FIG. 1, the display panel 1 has an active area AA and a non-active area NA connected to the active area AA. The active area AA is configured to present a display image and is provided with a plurality of light-emitting devices 40, each of which can be activated under control. The non-active area NA is arranged around the active area AA and is provided with a plurality of signal traces. Devices in the active area AA are electrically connected to a bonding assembly via the signal traces, to acquire control signals output by the bonding assembly and activate the corresponding light-emitting devices 40 according to the control signals. The bonding assembly may include at least one of electronic devices, such as a flexible printed circuit (FPC) and a driving chip.

The display panel 1 provided in this embodiment of the present disclosure includes a substrate 10, an isolation structure 30, and a plurality of light-emitting devices 40. In the active area AA, the layered structure of the display panel 1 in this embodiment of the present disclosure is similar to the layered structure of the display panel 1 provided in the above embodiments of the present disclosure, and thus will not be described in detail herein.

As shown in FIG. 6, in the non-active area NA, a plurality of (i.e., at least two) recessed portions 50 are provided in the isolation structure 30, at least one first via 60 is formed in the pixel defining layer 20, and at least one second via 70 is formed in the planarization layer 13. The first via 60 extends through the pixel defining layer 20, the second via 70 extends through the planarization layer 13, and the first vias 60 and the second vias 70 are arranged in a one-to-one correspondence. That is, an orthographic projection of each first via 60 on the substrate 10 is located within an orthographic projection of a corresponding second via 70 on the substrate 10. The support layer 31 of the isolation structure 30 is electrically connected to the power signal line in the conductive layer 12 via the first via 60 and the second via 70, and a VSS power signal is transmitted via the power signal trace. Further, the pixel defining layer 20 covers the surface of the planarization layer 13 facing away from the conductive layer 12 and the side surface of the planarization layer 13 facing the second via 70. The plurality of recessed portions 50 are arranged in a one-to-one correspondence with the plurality of first vias 60 and the plurality of second vias 70. Each recessed portion 50 is housed within a first via 60 and a second via 70, that is, the orthographic projection of the recessed portion 50 on the substrate 10 is located within the orthographic projections of the first via 60 and second via 70 on the substrate 10. In the cross-section perpendicular to the substrate 10, the recessed portion 50 has a smaller width than the first via 60 and the second via 70, thereby ensuring that part of the support layer 31 extends into the first via 60 and the second via 70 for electrical connection to the conductive layer 12. A spacing between two adjacent recessed portions 50 is less than or equal to 200 nm, and a spacing between two adjacent second vias 70 is less than 200 nm. For example, the spacing between two adjacent recessed portions 50 may be 150 nm, 100 nm, or 50 nm, and the spacing between two adjacent second vias 70 may be 150 nm, 100 nm, or 50 nm. Further, the plurality of recessed portions 50 include an adjacent first recessed portion 50A and second recessed portion 50B, and part of the orthographic projection of the pixel defining layer 20 on the substrate 10 is located between an orthographic projection of the first recessed portion 50A on the substrate 10 and an orthographic projection of the second recessed portion 50B on the substrate 10.

As shown in FIG. 6 or 7, the recessed portion 50 is recessed from a side of the isolation structure 30 facing away from the substrate 10 toward the substrate 10, and a depth of the recessed portion is a first depth d1. In a cross-section perpendicular to the substrate 10, the blocking layer 32 has a first film thickness T1, and the first depth d1 is greater than the first film thickness T1. That is, the recessed portion 50 extends through the blocking layer 32. The recessed portion 50 is recessed from the side of the support layer 31 facing away from the substrate 10 toward the substrate 10, with a depth of a second depth d2. The support layer 31 has a second film thickness T2, and the second depth d2 is less than or equal to the second film thickness T2. That is, the recessed portion 50 may or may not extend through the isolation structure 30.

In particular, each recessed portion 50 includes a first opening 51 and a second opening 52 that is in communication with the first opening 51. The first opening 51 is located on the side of the support layer 31 facing away from the substrate 10. As shown in FIGS. 6 and 7, the depth of the first opening 51 (i.e., the second depth d2) is less than or equal to the thickness of the support layer 31 (i.e., the second film thickness T2). That is, the first opening 51 may be embedded in a surface of the support layer 31 facing away from the substrate 10, as shown in FIG. 6, or may completely extend through the support layer 31, as shown in FIG. 7. The isolation structure 30 has a first surface 34 facing the power signal line. When the first opening 51 extends through the support layer 31, the bottom wall of the first opening 51 is coplanar with a second surface 35, allowing a surface of the power signal line on a side facing away from the substrate 10 to be partially exposed in the recessed portion 50. When the first opening 51 does not extend through the support layer 31, the bottom wall of the recessed portion 50 is non-coplanar with the second surface 35 and is located on a side of the second surface 35 facing away from the substrate 10. The second opening 52 extends through the blocking layer 32, and an orthographic projection of the second opening 52 on the substrate 10 is located within an orthographic projection of the first opening 51 on the substrate 10, thereby enabling the second opening 52 to be in communication with the first opening 51. In one embodiment, the depth of the first opening 51 is smaller than the thickness of the support layer 31, and the recessed portion 50 does not extend through the support layer 31. In this way, part of the support layer 31 is retained at a bottom of the recessed portion 50. Retaining more support layer material can reduce the overall resistance of the support layer 31, thereby lowering the power consumption of the display panel 1.

Further, in the display panel 1 provided in other embodiments of the present disclosure, as shown in FIG. 8, at least two recessed portions 50 may be housed within the same first via 60 and second via 70, that is, the orthographic projections of the at least two recessed portions 50 on the substrate 10 are located within the orthographic projections of the same first via 60 and second via 70 on the substrate 10, and each recessed portion 50 has a smaller width than the second via 70. The layered structure of the display panel 1 is similar to that of the display panel 1 provided in the embodiments of the present disclosure, and thus will not be described in detail herein.

To meet the bonding requirements between the support layer 31 and the conductive layer 12, a large-area support layer 31 is typically prepared in the non-active area NA. However, the problem of peeling may easily occur between the large-area support layer 31 and the film layers (e.g., the blocking layer 32) prepared in subsequent processes, causing abnormalities in the film layers within the non-active area NA. Therefore, in the embodiments of the present disclosure, recessed portions 50 are provided in the non-active area NA to relieve stress in the support layer 31 and the blocking layer 32, thereby solving the problem of peeling that easily occurs between the large-area support layer 31 and the film layers prepared in subsequent processes in the non-active area NA, and improving the effect of bonding between the support layer 31 and other film layers in the non-active area NA.

In the display panel and display apparatus provided in the embodiments of the present disclosure, a recessed portion is provided in the isolation structure located in the non-active area NA to alleviate stress in the isolation structure, thereby solving the problem of peeling that easily occurs between adjacent film layers of the isolation structure and improving the reliability of the display panel.

While the present disclosure is described herein with reference to specific implementations, it is to be understood that such embodiments are merely examples of the principles and applications of the present disclosure. Therefore, it is to be understood that various modifications may be made to the exemplary embodiments, and other arrangements may be devised, without departing from the spirit and scope of the present disclosure as defined by the appended claims. It is to be understood that the features described herein may be combined with different dependent claims in ways other than those explicitly described in the original claims. It is also to be understood that features described in one embodiment may be applied to other embodiments described herein.

What is claimed is:

1. A display panel, having an active area and a non-active area, the display panel comprising:
a substrate;
an isolation structure arranged on a side of the substrate and located in the active area and the non-active area, the isolation structure enclosing a plurality of isolation openings and having at least one recessed portion, the plurality of isolation openings being located in the active area, the at least one recessed portion being located in the non-active area, and the at least one recessed portion being recessed from a side of the isolation structure facing away from the substrate toward the substrate; and
a plurality of light-emitting devices, at least part of each light-emitting device being located in an isolation opening.

2. The display panel of claim 1, wherein the display panel comprises:
a driving layer arranged on a side of the substrate and located in the active area and the non-active area, the driving layer comprising at least one power signal line located in the non-active area; and
a pixel defining layer arranged on a side of the driving layer facing away from the substrate and located in the active area and the non-active area, the pixel defining layer enclosing a plurality of pixel openings and having at least one first via, the plurality of pixel openings being located in the active area and communicated with the corresponding isolation openings, the at least one first via being located in the non-active area, a surface of the at least one power signal line on a side facing away from the substrate being partially exposed through the at least one first via, and part of the isolation structure extending into the at least one first via and being electrically connected to the at least one power signal line.

3. The display panel of claim 2, wherein the driving layer further comprises a planarization layer arranged between the at least one power signal line and the pixel defining layer, wherein the planarization layer has at least one second via, and an orthographic projection of the at least one first via on the substrate is located within an orthographic projection of the at least one second via on the substrate;
a material of the planarization layer comprises an organic material;
the isolation structure is located on a side of the pixel defining layer facing away from the substrate; and
the pixel defining layer covers a side surface of the planarization layer facing the at least one second via.

4. The display panel of claim 2, wherein an orthographic projection of the at least one recessed portion on the substrate is located outside an orthographic projection of the at least one first via on the substrate.

5. The display panel of claim 2, wherein the at least one first via comprises a plurality of first vias, wherein
the at least one recessed portion comprises one or more recessed portions, the recessed portion being arranged between two adjacent first vias; or
the driving layer further comprises a planarization layer arranged between the at least one power signal line and the pixel defining layer, wherein the planarization layer has a plurality of second vias, an orthographic projection of the at least one first via on the substrate is located within an orthographic projection of at least one second via on the substrate, and the plurality of first vias and the plurality of second vias are arranged in a one-to-one correspondence.

6. The display panel of claim 2, wherein an orthographic projection of the recessed portion on the substrate is located within an orthographic projection of the pixel defining layer on the substrate.

7. The display panel of claim 2, wherein the driving layer further comprises a planarization layer arranged between the at least one power signal line and the pixel defining layer, and an orthographic projection of the recessed portion on the substrate is located within an orthographic projection of the planarization layer on the substrate.

8. The display panel of claim 4, wherein the recessed portion does not extend through the isolation structure; and
the isolation structure has a first surface facing the pixel defining layer, and a bottom wall of the recessed portion is located on a side of the first surface facing away from the substrate.

9. The display panel of claim 4, wherein the recessed portion extends through the isolation structure; and
a surface of the pixel defining layer on a side facing away from the substrate is partially exposed through the recessed portion.

10. The display panel of claim 2, wherein the pixel defining layer has a plurality of third vias in communication with corresponding recessed portions.

11. The display panel of claim 10, wherein in a cross-section perpendicular to the substrate, each third via has a smaller width than the recessed portion; or the plurality of third vias and the plurality of recessed portions are arranged in a one-to-one correspondence.

12. The display panel of claim 2, wherein
the at least one first via comprises a plurality of first vias, the at least one recessed portion comprises a plurality of recessed portions, and in a cross-section perpendicular to the substrate, the recessed portion has a smaller width than the first via; and
an orthographic projection of the recessed portion on the substrate is located within an orthographic projection of the corresponding first via on the substrate.

13. The display panel of claim 7, wherein the plurality of recessed portions comprise an adjacent first recessed portion and second recessed portion, and part of an orthographic projection of the pixel defining layer on the substrate is located between an orthographic projection of the first recessed portion on the substrate and an orthographic projection of the second recessed portion on the substrate.

14. The display panel of claim 13, wherein the recessed portion extends through the isolation structure; and the surface of the at least one power signal line on the side facing away from the substrate is partially exposed through the recessed portion; or
the recessed portion does not extend through the isolation structure; and the isolation structure has a second surface facing the pixel defining layer, and a bottom wall of the recessed portion is located on a side of the second surface facing away from the substrate.

15. The display panel of claim 2, wherein orthographic projections of at least two recessed portions on the substrate are located within an orthographic projection of the same first via on the substrate;
the recessed portions extend through the isolation structure; and
the surface of the at least one power signal line on the side facing away from the substrate is partially exposed through the recessed portions.

16. The display panel of claim 1, wherein the at least one recessed portion comprises a plurality of recessed portions, and a spacing between two adjacent recessed portions is not greater than 200 nm.

17. The display panel of claim 1, wherein the isolation structure comprises:
a support layer arranged on a side of the substrate; and
a blocking layer arranged on a side of the support layer facing away from the substrate, an orthographic projection of the blocking layer on the substrate covering an orthographic projection of the support layer on the substrate;
wherein the at least one recessed portion extends through at least the blocking layer; and
a material of the support layer comprises aluminum, or a material of the blocking layer comprises titanium.

18. The display panel of claim 17, wherein the at least one recessed portion is recessed from the side of the isolation structure facing away from the substrate toward the substrate by a first depth, and in a cross-section perpendicular to the substrate, the blocking layer has a first film thickness, the first depth being greater than the first film thickness; or the at least one recessed portion is recessed from the side of the support layer facing away from the substrate toward the substrate by a second depth, and the support layer has a second film thickness, the second depth being less than or equal to the second film thickness.

19. The display panel of claim 1, wherein the isolation structure comprises:
an isolation portion located in the active area and enclosing the plurality of isolation openings; and
an overlapping portion located in the non-active area, the at least one recessed portion being arranged on the overlapping portion;
wherein the isolation portion and the overlapping portion are integrally formed.

20. A display apparatus, comprising:
a display panel, having an active area and a non-active area, the display panel comprising:
a substrate;
an isolation structure arranged on a side of the substrate and located in the active area and the non-active area, the isolation structure enclosing a plurality of isolation openings and having at least one recessed portion, the plurality of isolation openings being located in the active area, the at least one recessed portion being located in the non-active area, and the at least one recessed portion being recessed from a side of the isolation structure facing away from the substrate toward the substrate; and
a plurality of light-emitting devices, at least part of each light-emitting device being located in an isolation opening.
